(19) United States
(12) Patent Application Publication
(10) Pub. No.: US 2007/0232030 A1
(43) Pub. Date: Oct. 4, 2007

(54) Semiconductor-wafer processing method using fluid-like layer

(75) Inventor: Hokuto Kumagai, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/727,303

(22) Filed: Mar. 26, 2007

(30) Foreign Application Priority Data
Mar. 28, 2006 (JP) 2006-087548

(51) Int. Cl. H01L 21/20; H01L 21/302

(52) U.S. Cl. 438/478; 257/E21.237; 438/691

(57) ABSTRACT

In a method for processing a semiconductor wafer, having a plurality of solder bumps bonded on a front surface thereof, a fluid-like layer is formed on the front surface of the semiconductor wafer. A holder sheet is prepared, and has a support layer, and an adhesive layer formed on a surface of the support layer and exhibiting a fluidness. The fluid-like layer is covered with the holder sheet such that the adhesive layer of the holder sheet is rested on a surface of the fluid-like layer, and the adhesive layer of the holder sheet is transformable so as to conform with a configuration of the surface of the fluid-like layer due to the fluidness of the adhesive layer of the holder sheet. A rear surface of the semiconductor wafer is mechanically ground so that the thickness of the semiconductor wafer is reduced to a target value. The holder sheet is peeled from the surface of the fluid-like layer.

### BACKGROUND OF THE INVENTION

1. Field of the Invention

The present invention generally relates to a method for processing a semiconductor wafer having a plurality of solder bumps bonded on a front surface thereof, and more particularly relates to a method for grinding a rear surface of such a semiconductor wafer to reduce a thickness of the semiconductor wafer.

2. Description of the Related Art

In a representative conventional method for manufacturing semiconductor devices, a semiconductor wafer such as a silicon wafer is prepared, and a front surface of the silicon wafer is sectioned into a plurality of semiconductor chip areas by defining so-called scribe line areas thereon. Then, the silicon wafer is processed by using a well-known variety of processes, such as a photolithography and etching process, a chemical vapor deposition process, a sputtering process and so on, such that a semiconductor chip or device is produced in each of the semiconductor chip areas. Thereafter, the silicon wafer is subjected to a dicing process in which the silicon wafer is cut along the scribe line areas, so that the semiconductor devices are separated from each other.

Conventionally, there is a demand for a smaller thickness in semiconductor devices. In order to make the thickness of the semiconductor devices small, before the dicing process, the silicon wafer is subjected to a grinding process in which the rear surface of the silicon wafer is mechanically ground to thereby reduce the thickness of the semiconductor wafer.

The grinding process is carried out by using a grinding machine, and the grinding machine includes a suction stage having a plurality of holes which are communicated with a vacuum pump. The front surface of the silicon wafer is covered with a suitable resin sheet having an adhesive layer, and the silicon wafer is set on the suction stage such that the resin sheet is in contact with the suction stage. Then, by operating the vacuum pump, the resin sheet carrying the silicon wafer is sucked to and fixed on the suction stage. Subsequently, a grinding wheel forming a part of the grinding machine is applied to and moved on the rear surface of the silicon wafer, resulting in reduction in the thickness of the silicon wafer.

A first prior art wafer-grinding method, as disclosed in JP-S61-141142 A, is directed to grinding of a silicon wafer which has an irregularity on a front surface thereof.

In particular, the silicon wafer has a plurality of semiconductor devices produced on the front surface thereof, and each of the semiconductor devices has a polyimide layer formed thereon. Each of the polyimide layers serves as a protective layer for protecting the corresponding semiconductor device from being exposed with alpha rays, and has a thickness falling within a range between 10 μm and 80 μm. Thus, the front surface of the semiconductor wafer has an irregularity due to the formation of the polyimide layers.

In the first prior art wafer-grinding method, the front surface of the silicon wafer is covered with a rubber sheet having an adhesive coating, and thus the irregularity of the front surface of the silicon wafer is absorbed due to an elasticity of the rubber sheet. Namely, an outer surface of the rubber sheet is flat regardless of the irregularity of the front surface of the silicon wafer. Accordingly, it is possible to properly set the silicon wafer on the suction stage of the grinding machine so that the flat outer surface of the rubber sheet is tightly sucked on the suction stage during the grinding operation.

A second prior art wafer-grinding method, as disclosed in JP-2004-530302 A, is directed to grinding of a silicon wafer which has a plurality of solder bumps bonded on a front surface thereof.

In the second prior art wafer-grinding method, each of the solder bumps is formed as a stud-shaped solder bump having a trapezoid cross section, and the stud-shaped solder bump has a height falling within a range between 150 μm and 250 μm, and a diameter falling within a range between 300 μm and 500 μm. Namely, the front surface of the silicon wafer used in the second prior art wafer-grinding method has a considerably larger irregularity in comparison with that of the front surface of the silicon wafer used in the aforesaid first prior art wafer-grinding method, and the large irregularity cannot be absorbed by the rubber sheet used in the aforesaid first prior art wafer-grinding method.

Thus, in the second prior art wafer-grinding method, a holder sheet, which includes a support layer, and an adhesive layer formed on a surface of the support layer, is used. The adhesive layer exhibits a suitable fluidness, and has a thickness which is larger than the height of the stud-shaped solder bumps. The front surface of the silicon wafer is covered with the holder sheet such that the stud-shaped solder bumps are buried in the adhesive layer of the holder sheet. Namely, the large irregularity of the front surface of the silicon wafer is absorbed by burying the stud-shaped solder bumps in the adhesive layer, and thus an outer surface of the support layer of the holder sheet is flat regardless of the large irregularity of the front surface of the silicon wafer. Accordingly, it is possible to properly set the silicon wafer on the suction stage of the grinding machine so that the flat outer surface of the support layer of the holder sheet is tightly sucked on the suction stage during the grinding operation.

Note that each of the stud-shaped solder bumps may be formed by using a conventional wire-bonding machine.

A third prior art wafer-grinding method, as disclosed in JP-2000-031185 A, is also directed to grinding of a silicon wafer which has a plurality of solder bumps bonded on a front surface thereof.

In the third prior art wafer-grinding method, the solder bumps are formed by depositing pieces of solder paste on the front surface of the silicon wafer with using a screen printing process, by defining a flux layer on the pieces of solder paste so that the pieces of solder paste are buried in the flux layer, and by thermally fusing the pieces of solder paste using a so-called reflow process. As a result, each of the solder bumps is shaped as a spherical solder bump buried in the flux layer.

Then, a thin adhesive sheet having two adhesive coatings formed on both the surfaces thereof is prepared, and is adhered to the surface of the flux layer of the silicon wafer using one of the adhesive coatings. Subsequently, the silicon wafer with the adhesive sheet is set on and adhered to a stage of a grinding machine using the other adhesive coating. Thereafter, the rear surface of the silicon wafer is mechanically ground by a grinding wheel of the grinding machine so that the thickness of the silicon wafer is reduced to a target value.

### SUMMARY OF THE INVENTION

It has now been discovered that the above-mentioned prior art methods have problems to be solved as mentioned hereinbelow.

In the aforesaid second prior art wafer-grinding method, when spherical solder bumps are substituted for the stud-like solder bumps, it is impossible to properly carry out the grinding operation of the silicon wafer for the reasons stated in detail hereinafter.

Also, in the aforesaid third prior art wafer-grinding method, the surface of the flux layer will have an inevitable irregularity, and thus the silicon wafer cannot be sufficiently adhered to the stage of the grinding machine due to the irregularity of the surface of the flux layer.

In accordance with an aspect of the present invention, there is provided a method for processing a semiconductor wafer having a plurality of solder bumps bonded on a front surface thereof. In the method, a fluid-like layer is formed on the front surface of the semiconductor wafer. A holder sheet is prepared, having a support layer, and an adhesive layer is formed on a surface of the support layer exhibiting a fluidness. The fluid-like layer is covered with the holder sheet such that the adhesive layer of the holder sheet is rested on a surface of the fluid-like layer, and the adhesive layer of the holder sheet is transformable so as to conform with a configuration of the surface of the fluid-like layer due to the fluidness of the adhesive layer of the holder sheet. A rear surface of the semiconductor wafer is mechanically ground so that a thickness of the semiconductor wafer is reduced to a target value, and the holder sheet is peeled from the surface of the fluid-like layer.

The fluid-like layer may be formed of an anti-oxidizing agent solution to prevent the solder bumps from being oxidized. The anti-oxidizing agent solution may comprise a fluid-like flux solution.

In the method, the fluid-like layer may be removed from the front surface of the semiconductor wafer. When the removal of the fluid-like layer is carried out, it may exhibit a setting property. In this case, the fluid-like layer is partially set after the formation of the fluid-like layer on the front surface of the semiconductor wafer is completed.

Also, when the fluid-like layer is removed from the front surface of the semiconductor wafer, it is preferable that the fluid-like layer is aqueous so that the removal of the fluid-like layer can be easily carried out with a water washing. For example, the fluid-like layer may be formed of a glycol-based solution, an organic resist solution or the like.

In the method, the adhesive layer of the holder sheet may have a thickness larger than a height of the solder bumps.

Also, the adhesive layer of the holder sheet may exhibit a high adhesive property to be allowed to be sufficiently adhered to the surface of the fluid-like layer. In this case, the adhesive property of the adhesive layer of the holder sheet is lowered so that the peeling of the holder sheet from the surface of the fluid-like layer can be easily carried out. Preferably, the adhesive layer of the holder sheet exhibits a setting property, and the adhesive layer is set to thereby lower the adhesive property thereof. The setting property of the adhesive layer may be either a thermosetting property or a photosetting property.

In the method, a dicing sheet may be adhered to the rear surface of the semiconductor wafer after the mechanical grinding of the rear surface is completed, and the semiconductor wafer may be subjected to a dicing process in which the semiconductor wafer is cut into a plurality of semiconductor devices. Preferably, the dicing sheet exhibits a setting property, and the dicing sheet is set so that the semiconductor devices can easily come off the dicing sheet.

In the method, half-cut grooves may be formed in the front surface of the semiconductor wafer along scribe line areas defined thereon before the formation of the fluid-like layer on the front surface of the semiconductor wafer is carried out. In this case, each of the half-cut grooves has a depth which is larger than the aforesaid target value so that the semiconductor wafer is separated into a plurality of semiconductor devices when the mechanical grinding of the rear surface of the semiconductor wafer is completed. Also, an adhesive support sheet may be adhered to the rear surface of the semiconductor wafer. The adhesive support sheet may exhibit a setting property, and the adhesive support sheet is set so that the semiconductor devices can easily come off the adhesive support sheet. Also, the adhesive support sheet should be nonreactive to the fluid-like layer.

### BRIEF DESCRIPTION OF THE DRAWINGS

The present invention will be more clearly understood from the description set forth below, with reference to the accompanying drawings, wherein:

FIGS. 1A to 1L are explanatory cross-sectional views for explaining a first embodiment of the method for processing a semiconductor wafer according to the present invention;

FIGS. 2A to 2F are explanatory cross-sectional views for explaining a comparative method for processing a semiconductor wafer;

FIGS. 3A and 3B are explanatory cross-sectional views for further explaining the comparative method of FIGS. 2A to 2F;

FIGS. 4A and 4B are explanatory cross-sectional views for further explaining the comparative method of FIGS. 2A to 2F;

FIGS. 5A to 5J are explanatory cross-sectional views for explaining a second embodiment of the method for processing a semiconductor wafer according to the present invention; and

FIG. 6 is an explanatory cross-sectional view for further explaining the comparative method of FIGS. 2A to 2F.

### DESCRIPTION OF THE PREFERRED EMBODIMENTS

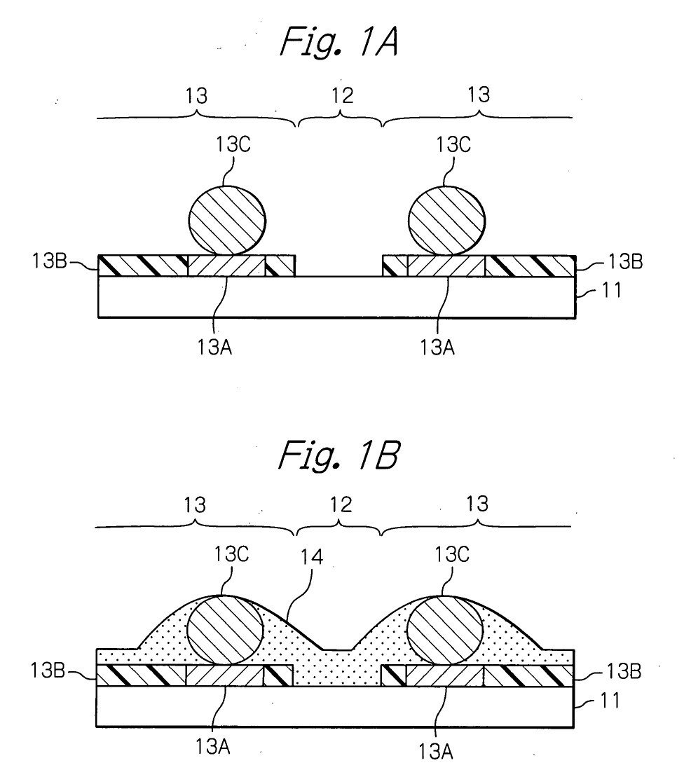

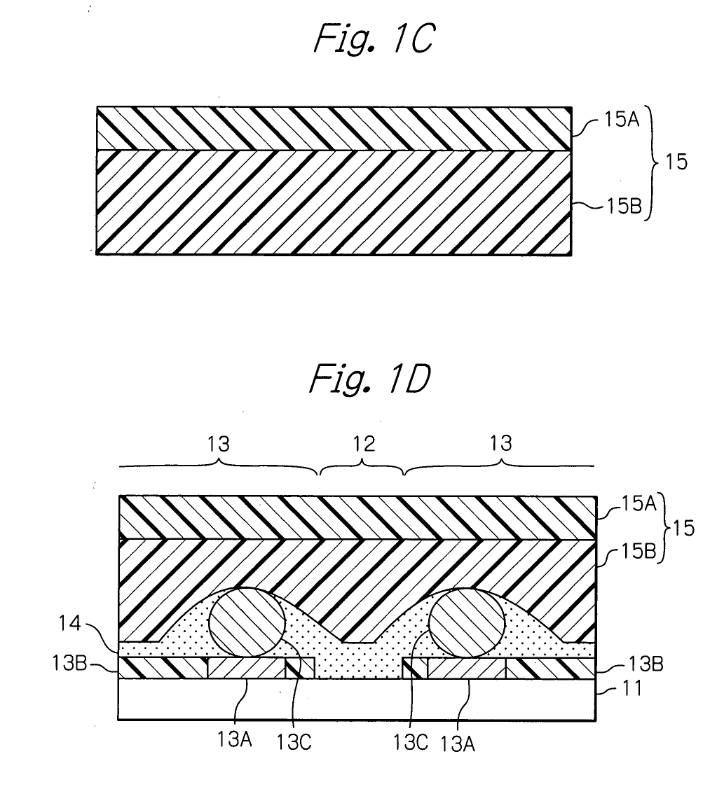

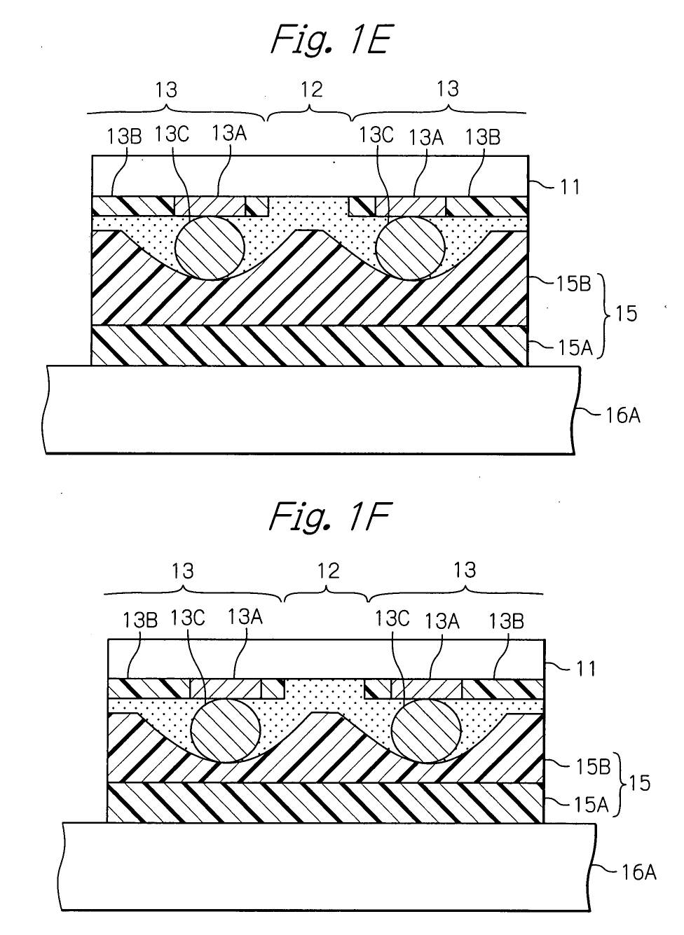

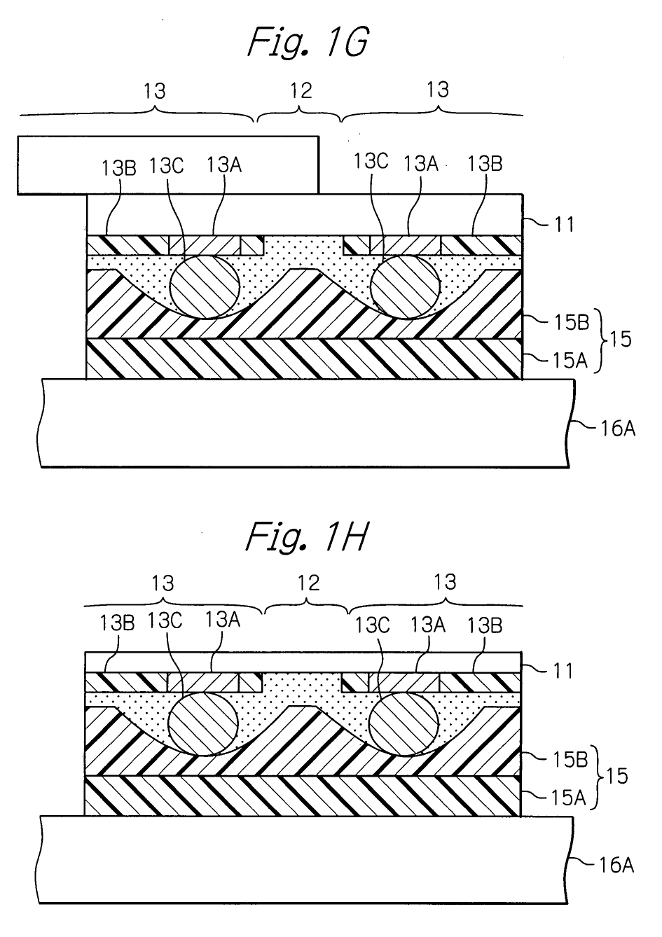

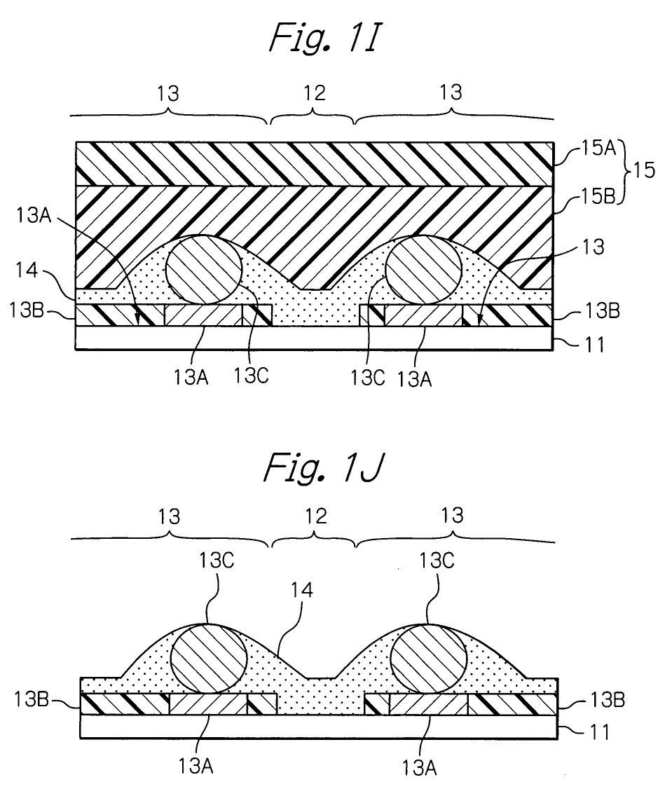

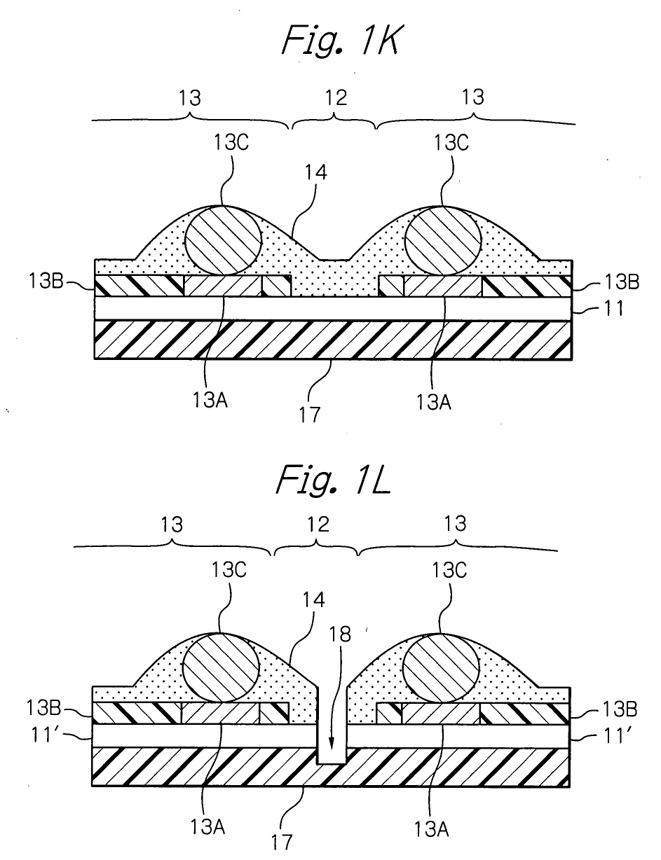

With reference to FIGS. 1A to 1L which are partial cross-sectional views, a first embodiment of the method for processing a semiconductor wafer according to the present invention will now be explained below.

First, referring to FIG. 1A, a semiconductor wafer 11 such as a silicon wafer is prepared. A front surface of the semiconductor wafer or silicon wafer 11 is sectioned into a plurality of chip areas 13 by defining so-called scribe line areas, only one of which is representatively shown and indicated by reference 12, and a semiconductor chip or device is already produced in each of the chip areas 13 by using a well-known variety of processes, such as a photolithography process, an etching process, a chemical vapor deposition (CVD) process, a sputtering process, a plating process and so on.

In the silicon wafer 11, a plurality of electrode pads 13A are formed on each of the semiconductor chip areas 13. The formation of the electrode pads 13A may be carried out by forming a suitable metal layer on the front surface of the silicon wafer 11 with using a CVD process, and by patterning the metal layer using a photolithography and etching process and so on. Note, in FIG. 1A, only one of the electrode pads 13A is representatively shown on each of the semiconductor chip areas 13. A suitable metal such as copper (Cu), aluminum (Al) or the like may be used for the electrode pads 13A. In each of the semiconductor chip devices 13, the electrode pads 13A may be arrayed at a pitch from 50 μm to 200 μm.

Also, in the silicon wafer 11, a polyimide layer 13B is formed on each of the semiconductor chip areas 13. The formation of the polyimide layers 13B may be carried out by coating the front surface of the silicon wafer 11 with polyimide, and by patterning the coating of polyimide using a photolithography and etching process and so on. Note that each of the polyimide layers 13B may have a thickness of 10 μm, and serves as a protective layer for protecting the corresponding semiconductor device from being exposed with alpha rays.

Further, in the silicon wafer 11, a plurality of solder bumps 13C are formed on and bonded to each of the respective electrode pads 13A. The formation of the solder bumps 13C may be carried out by depositing pieces of solder paste on the respective electrode pads 13A using a screen printing process, and by thermally fusing the pieces of solder paste using a so-called reflow process. Thus, each of the solder bumps 13C features a spherical configuration due to the reflow process or thermal fusing process of the pieces of solder paste. Note that each of the spherical solder bumps 13C may have a height or diameter falling within a range between 70 μm and 200 μm, and is composed of a suitable metal such as tin (Sn), silver (Ag), copper (Cu) or the like, or an alloy containing at least two of tin (Sn), silver (Ag), copper (Cu) and so on.

Next, referring to FIG. 1B, the front surface of the silicon wafer 11 is coated with a fluid-like material such as a liquid-like material, a gel-like material, a paste-like material or the like to thereby form a fluid-like layer 14 on the front surface of the silicon wafer 11. The fluid-like layer 14 may be composed of a suitable liquid-like material exhibiting a wettability to the silicon wafer 11, the electrode pads 13A, the polyimide layers 13B and the spherical solder bumps 13C.

For example, for the liquid-like material, a liquid-like flux solution may be used. Note that the liquid-like flux solution serves as an anti-oxidizing agent solution for the solder bumps 13C.

On the other hand, for the liquid-like material, a suitable aqueous solution such as a glycol-based solution containing polyvinyl alcohol, ethylene alcohol or the like, an organic resist solution or the like may be used.

There are many fine spatial nests on the front surface of the silicon wafer 11. For example, the fine spaces are defined as spatial nests between the electrode pads 13A and the spherical solder bumps 13C, and the scribe line areas 12 are defined as spatial nests between the two adjacent polyimide layers 13B. Nevertheless, when the fluid-like or liquid-like layer 14 is formed on the front surface of the silicon wafer 11, the fine spatial nests are filled with the fluid-like material due to the wettability to the silicon wafer 11, the electrode pads 13A, the polyimide layers 13B and the spherical solder bumps 13C, as shown in FIG. 1B.

Also, the fluid-like or liquid-like layer 14 has a suitable viscosity and a suitable surface tension so that the fluid-like material is prevented from flowing out of the front surface of the silicon wafer 11. That is, a surface of the liquid-like layer 14 is undulated due to the existence of the spherical solder bumps 13C, and the undulated surface of the liquid-like layer 14 is maintained due to both the suitable viscosity and the surface tension of the liquid-like material.

Further, the liquid-like layer 14 may exhibit a setting property such as a thermosetting property, a photosetting property or the like, if necessary. In this case, the liquid-like layer 14 is merely partially set so that a configuration of the liquid-like layer 14 can be stably maintained.

For example, when the liquid-like layer 14 exhibits the thermosetting property, the liquid-like layer 14 is thermally heated so as to be partially set. Also, when the liquid-like layer 14 exhibits the photosetting property, the liquid-like layer 14 is irradiated with suitable light rays such as ultraviolet rays so as to be partially set.

On the other hand, referring to FIG. 1C, a holder sheet 15 is prepared. The holder sheet 15 includes a support layer 15A, and an adhesive layer 15B formed on a surface of the support layer 15A. The support layer 15A may be formed as a hard resin layer composed of, for example, high molecular polyolefin, and the adhesive layer 15B may be formed as an adhesive resin layer composed of, for example, low molecular polyolefin. Also, when the support layer 15A is formed as the high molecular polyolefin layer, the adhesive layer 15B may be formed as a suitable prepolymer layer exhibiting either a thermosetting property or a photosetting property. Note that the adhesive layer has a considerably larger thickness than the height or diameter (70-200 μm) of the spherical solder bumps 13C. In short, the adhesive layer 15B is sticky, but exhibits a suitable fluidness.

Next, referring to FIG. 1D, the liquid-like layer 14 is covered with the holder sheet 15 such that the adhesive layer 15B of the holder sheet 15 is directly rested on the undulated surface of the liquid-like layer 14. Thus, the adhesive layer 15B is transformed and undulated so as to conform with the undulated surface of the liquid-like layer 14 due to the fluidness of the adhesive layer 15B.

Next, referring to FIG. 1E, the holder sheet 15 carrying the silicon wafer 11 is set on a suction stage 16A forming a part of a grinding machine (not shown), such that the support layer 15A of the holder sheet 15 is rested on a top surface of the suction stage 16A. The suction stage 16A has a plurality of holes (not shown) formed in the top surface thereof, and the holes are communicated with a vacuum pump (not shown) forming another part of the grinding machine.

Next, referring to FIG. 1F, the holder sheet 15 is sucked against the top surface of the suction stage 16A by operating the aforesaid vacuum pump, so that the holder sheet 15 carrying the silicon wafer 11 is securely fixed on the suction stage 16A, with the adhesive layer 15B being compressed due to the suction force exerted on the holder sheet 15 by the suction stage 16A.

Next, referring to FIG. 1G, a grinding wheel 16B forming yet another part of the aforesaid grinding machine (not shown) is applied to and is moved on the rear surface of the silicon wafer 11 while an abrasive slurry (not shown) is supplied to the rear surface of the silicon wafer 11, whereby the silicon wafer 11 is subjected to a mechanical grinding process.

Next, referring to FIG. 1H, the mechanical grinding process of the silicon wafer 11 is continued until a thickness of the silicon wafer 11 is reduced to a target value. Thereafter, the operation of the aforesaid vacuum pump is stopped so that the holder sheet 15 carrying the silicon wafer 11 is released from the suction force exerted thereon by the suction stage 16A.

Next, referring to FIG. 1I, the holder sheet 15 carrying the silicon wafer 11 having the reduced thickness is removed from the suction stage 16A.

If the adhesive layer 15B is formed as the prepolymer layer exhibiting the thermosetting property, the holder sheet 15 is heated to thereby cause polymerization in the prepolymer layer 15B, whereby an adhesive property of the adhesive layer 15B is lowered. Also, if the adhesive layer 15B is formed as the prepolymer layer exhibiting the photosetting property, the holder sheet 15 is irradiated with suitable light rays such as ultraviolet rays to thereby cause polymerization in the prepolymer layer 15B, whereby an adhesive property of the adhesive layer 15B is lowered. In either event, when the adhesive layer 15B is formed as the prepolymer layer exhibiting either the thermosetting property or the photosetting property, it is changed into a polymerized layer featuring the lowered adhesive property.

Next, referring to FIG. 1J, the holder sheet 15 is peeled from the liquid-like layer 14. Note, although it is very difficult to clearly peel the prepolymer layer 15B itself from the liquid-like layer 14, the polymerized layer 15B featuring the lowered adhesive property can be easily and clearly peeled from the liquid-like layer 14.

When the liquid-like layer 14 is not formed of the liquid-like flux solution, the liquid-like layer 14 may be removed from the front surface of the silicon wafer 11. Note that the removal of the liquid-like layer 14, which is formed of the glycol-based solution, the organic resist solution or the like, can be easily carried out using a pressurized water washing or an air/water washing.

Next, referring to FIG. 1K, a dicing sheet 17 having an adhesive coating (not shown) is adhered to the rear surface of the silicon wafer 11. Note that the peeling of the holder sheet 15 and the removal of the liquid-like layer 14 may be carried out after the adhesion of the dicing sheet 17 to the rear surface of the silicon wafer 11 is completed.

Next, referring to FIG. 1L, the silicon wafer 11 is subjected to a dicing process, in which the silicon wafer 11 is cut along the scribe line areas 12 by a rotary cutter (not shown) so that cutting grooves 18, only one of which is representatively shown, are formed along the scribe line areas 12, whereby the semiconductor chip areas 13 are separated from each other, with each of the semiconductor chip areas 13 having a silicon substrate 11′ derived from the silicon wafer 11. The cutting groove 18 partially penetrates in the dicing sheet 17, and thus the separated semiconductor substrates 11′ are held by the dicing sheet 17, to thereby prevent the semiconductor substrates 11′ from being disorderly separated from each other. Note that each of the separated substrates 11′ carrying the electrode pads 13A, the polyimide layer 13B and the spherical solder bumps 13C is called a flip-chip type semiconductor device.

When the liquid-like layer 14 is formed of the liquid-like flux solution, and when each of the flip-chip type semiconductor devices is flipped over and mounted on a wiring board or interposer, the solider bumps 13C can be soldered on electrode pads on the interposer without supplying flux to the spherical solder bumps 13C because each of the flip-chip type semiconductor devices is already provided with the liquid-like flux layer 14.

The adhesive coating of the dicing sheet 17 may exhibit a setting property such as a thermosetting property, a photosetting property or the like. For example, when the adhesive coating of the dicing sheet 17 exhibits the thermosetting property, the dicing sheet 17 is thermally heated so as to be set, whereby each of the flip-chip type semiconductor devices can easily come off from the dicing sheet 17. Also, when the adhesive coating layer of the dicing sheet 17 exhibits the photosetting property, the dicing sheet 17 is irradiated with suitable light rays such as ultraviolet rays so as to be set, whereby each of the flip-chip type semiconductor devices can easily come off from the dicing sheet 17.

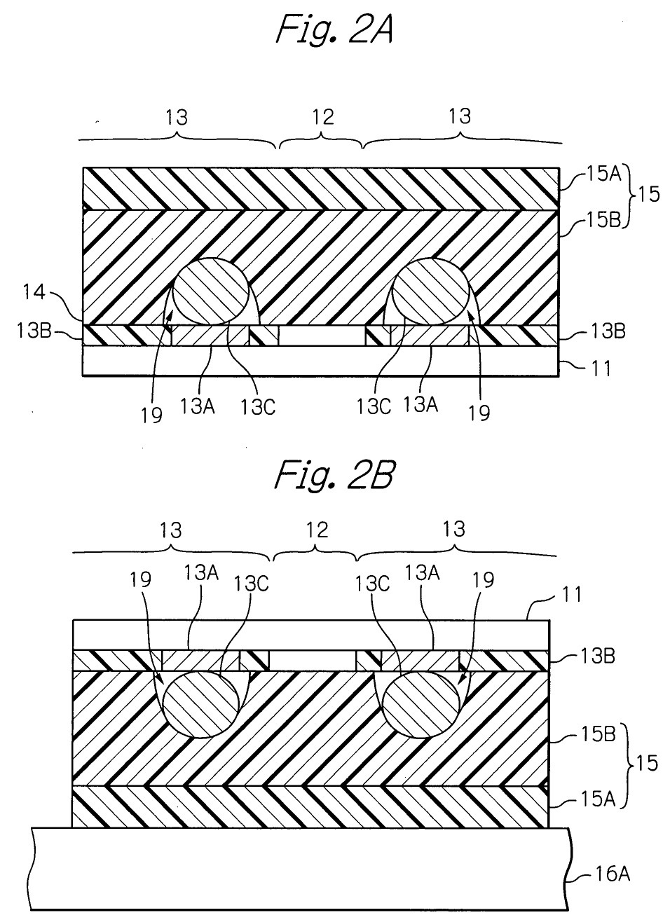

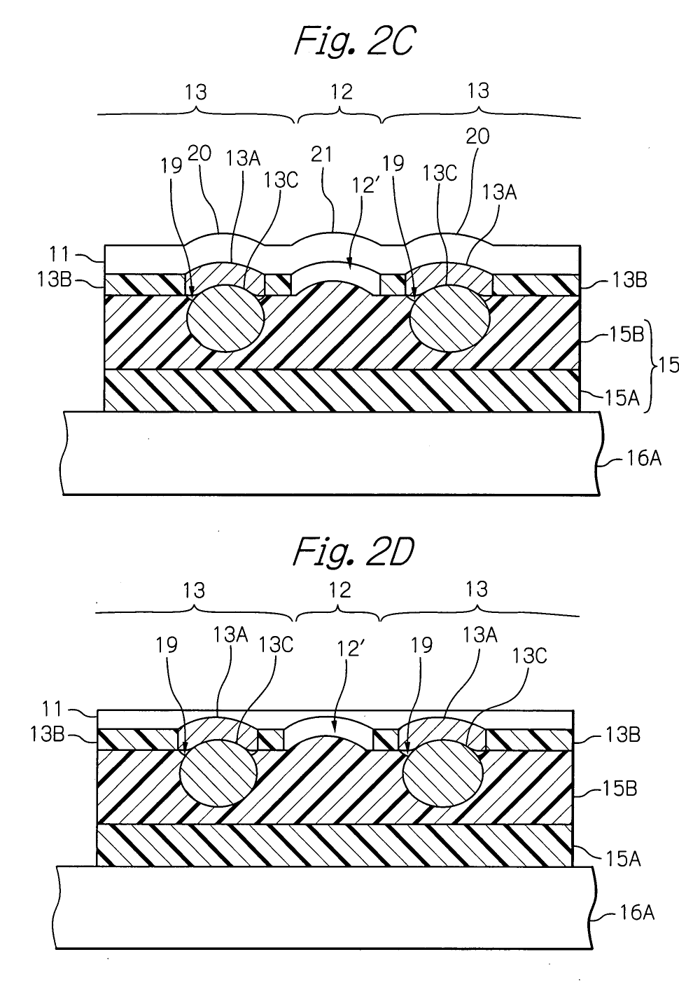

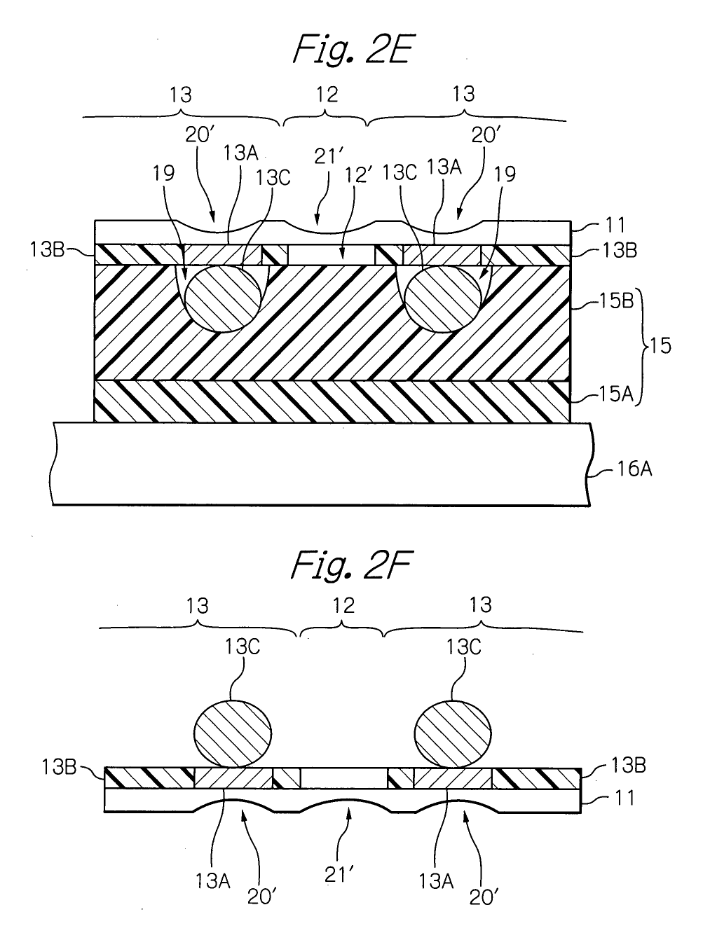

With reference to FIGS. 2A to 2F which are partial cross-sectional views, a comparative method for processing a semiconductor wafer will be now explained below.

First, referring to FIG. 2A, the silicon wafer 11 of FIG. 1A is directly covered with the holder sheet 15 without the liquid-like layer 14 (see: FIG. 1B) being formed on the front surface of the silicon wafer 11. In this case, a spatial nest or cavity 19 is apt to be defined beneath each of the spherical solder bumps 13C. Also, the scribe line area 12 cannot be necessarily filled with the material of the adhesive layer 15B of the holder sheet 15, and thus a spatial nest or a groove-like cavity 12′ is defined in the scribe line area 12.

Next, referring to FIG. 2B, the holder sheet 15 carrying the silicon wafer 11 is set on the suction stage 16A of the grinding machine (not shown), such that the support layer 15A of the holder sheet 15 is rested on the top surface of the suction stage 16A. As stated above, the suction stage 16A has the holes (not shown) communicated with the vacuum pump (not shown).

Next, referring to FIG. 2C, the holder sheet 15 is sucked against the top surface of the suction stage 16A by operating the vacuum pump, so that the holder sheet 15 carrying the silicon wafer 11 is securely fixed on the suction stage 16A, and so that the adhesive layer 15B is compressed due to the suction force exerted on the holder sheet 15 by the suction stage 16A.

As a result, air captured in each of the spatial nests or cavities 19 is compressed, so that the silicon wafer 11 is deformed at each of the locations of the spherical solder bumps 13C due to the pressure of the compressed air, resulting in formation of swells 20 on the rear surface of the silicon wafer 11 at the locations of the spherical solder bumps 13C.

Similarly, air captured in the groove-like cavity 12′ is compressed, so that the silicon wafer 11 is further deformed at the location of the groove-like cavity 12′ in the scribe line area 12 due to the pressure of the compressed air, resulting in formation of a swell 21 on the rear surface of the silicon wafer 11 at the location of the groove-like cavity 12′ in the scribe line area 12.

Next, referring to FIG. 2D, the rear surface of the silicon wafer 11 is mechanically ground in substantially the same manner as explained with reference to FIGS. 1G and 1H until a thickness of the silicon wafer 11 is reduced to a target value.

Next, referring to FIG. 2E, the operation of the aforesaid vacuum pump is stopped so that the adhesive layer 15B of the holder sheet 15 is released from the compression. Thus, the adhesive layer 15B is returned to the original configuration so that the silicon wafer 11 is released from the deformation (see: FIG. 2C). As a result, recesses 20′ are defined in the ground rear surface of the silicon wafer 11 at the locations of the spherical solder bumps 13C, and a recess 21′ is defined in the ground rear surface of the silicon wafer 11 at the location of the scribe line area 12.

Next, referring to FIG. 2F, the holder sheet 15 carrying the silicon wafer 11 having the reduced thickness is removed from the suction stage 16A, and then the holder sheet 15 is peeled from the front surface of the silicon wafer 11.

Thereafter, the silicon wafer 11 is subjected to a dicing process in which the silicon wafer 11 is cut along the scribe line areas 12, so that the semiconductor chip areas 13 are separated from each other, resulting in a manufacture of the semiconductor chips or devices. Nevertheless, during the dicing process, the silicon wafer 11 is susceptible to breakage due to the existence of the recesses 20′ and 21′ thereof. Also, each of the separated semiconductor chips or devices tends to includes defects due to the existence of the recesses 20′. At any rate, a manufacturing yield may considerably decline in the manufacture of the semiconductor chips or devices.

By contrast, in the first embodiment of FIGS. 1A to 1L, since the liquid-like layer 14 is formed on the front surface of the silicon wafer 11, and since the liquid-like layer 14 is covered with the holder sheet 15, no spatial nests or cavities are defined on the front surface of the silicon wafer 11. Accordingly, the rear surface of the silicon wafer 11 can be ground without being subjected to any deformation, so that any recesses cannot be defined in the ground rear surface of the silicon wafer 11, resulting in an increase of a manufacturing yield of the semiconductor chips or devices.

In the above-mentioned comparative method of FIGS. 2A to 2F, a part of the spherical solder bumps 13C may be completely buried in the adhesive layer 15B without no spatial nests or cavities (19) being defined beneath the spherical solder bumps 13C. In this case, when the adhesive layer 15B of the holder sheet 15 is formed as a prepolymer layer exhibiting a photosetting property, the peeling of the holder sheet 15 from the front surface of the silicon wafer 11 cannot be properly carried out, as stated below.

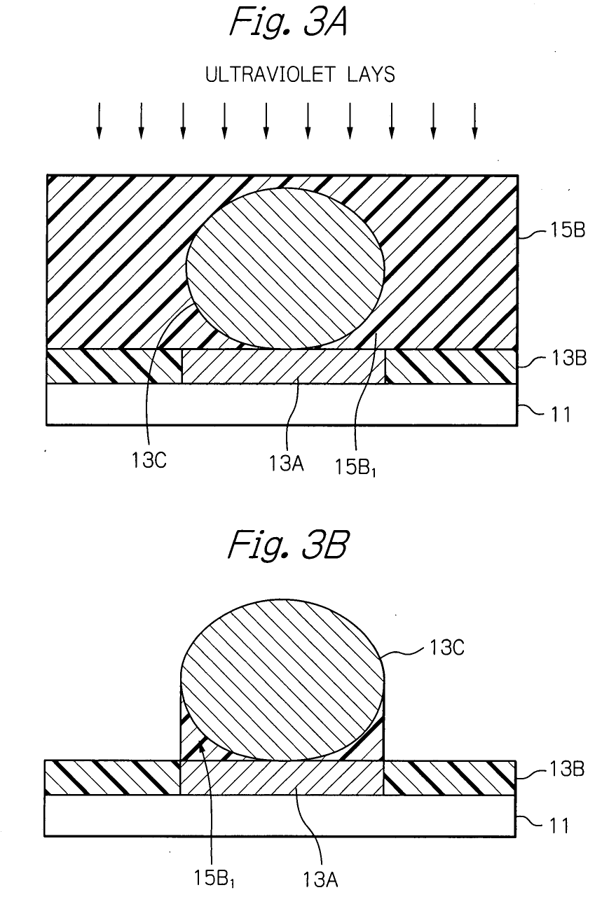

As shown in FIG. 3A which is a partially-enlarged cross-sectional view, the spherical solder bump 13C is completely buried in the adhesive layer 15B of the holder sheet 15, which is formed as the prepolymer layer exhibiting a photosetting property. After the mechanical grinding of the rear surface of the silicon wafer 11 is completed, the adhesive layer or prepolymer layer 15B is irradiated with ultraviolet rays to thereby cause polymerization in the prepolymer layer 15B, as symbolically shown by arrows in FIG. 3A. Nevertheless, a part 15B, of the prepolymer layer 15B, which is sited beneath the spherical solder bump 13C, cannot be irradiated with the ultraviolet rays, and thus the polymerization cannot be caused in the part 15B₁. Namely, the part 15B₁ still remains as a prepolymer part.

Then, as shown in FIG. 3B which is a partially-enlarged cross-sectional view, when the holder sheet 15 is peeled from the front surface of the silicon wafer 11, the prepolymer part 15B₁ is left beneath the spherical solder bump 13C as it stands. Of course, although the prepolymer part 15B₁ has to be removed from the front surface of the silicon wafer 11, the removal of the prepolymer part 15B₁ results in an increase of the manufacturing cost of the semiconductor chips or devices.

By contrast, in the first embodiment of FIGS. 1A to 1L, although the adhesive layer 15B of the holder sheet 15 may be formed as the prepolymer layer exhibiting a photosetting property, the polymerization can be wholly and completely caused in the prepolymer layer 15B because the holder sheet 15 is applied to the liquid-like layer 14 in which the spherical solder bumps 13C are buried.

Also, in the above-mentioned comparative method of FIGS. 2A to 2F, for example, when each of the spherical solder bumps 13C is composed of an alloy containing, for example, tin (Sn), silver (Ag) and copper (Cu), the peeling of the holder sheet 15 from the front surface of the silicon wafer 11 cannot be properly carried out, as stated below.

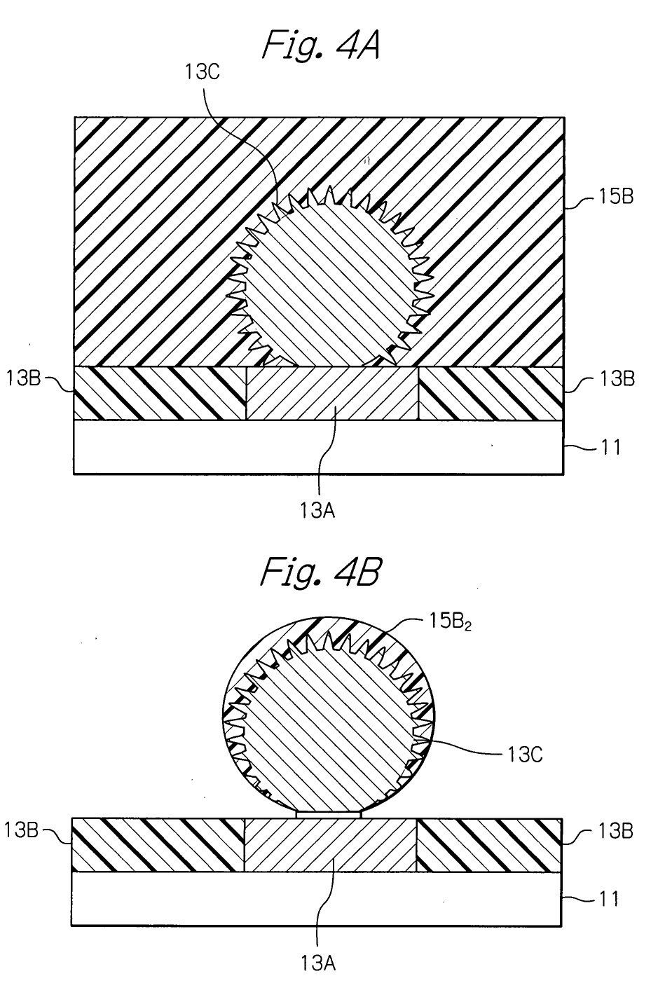

As shown in FIG. 4A which is a partially-enlarged cross-sectional view, the spherical solder bump 13C composed of the alloy has a rough surface featured by a plurality of burs because the tin (Sn) component, the silver (Ag) component and the copper (Cu) component contained in the alloy have different melting points. When the spherical solder bump 13C is buried in the adhesive layer 15B of the holder sheet 15, the material of the adhesive layer 15B penetrates into clearances between the burs.

As shown in FIG. 4B which is a partially-enlarged cross-sectional view, when the holder sheet 15 is peeled from the front surface of the silicon wafer 11 after the mechanical grinding of the rear surface of the silicon wafer 11 is completed, a part 15B₂ of the adhesive layer 15B, which penetrates into the clearances between the burs of the spherical solder bumps 13C, is left around the spherical solder bump 13C. Similar to the case of FIGS. 3A and 3B, although the part 15B₂ has to be removed from the spherical solder bump 13C, the removal of the part 15B₂ results in an increase of the manufacturing cost of the semiconductor chips or devices.

By contrast, the first embodiment of FIGS. 1A to 1L, is free from the above-mentioned removal problem because the spherical solder bumps 13C are covered with the liquid-like layer 14.

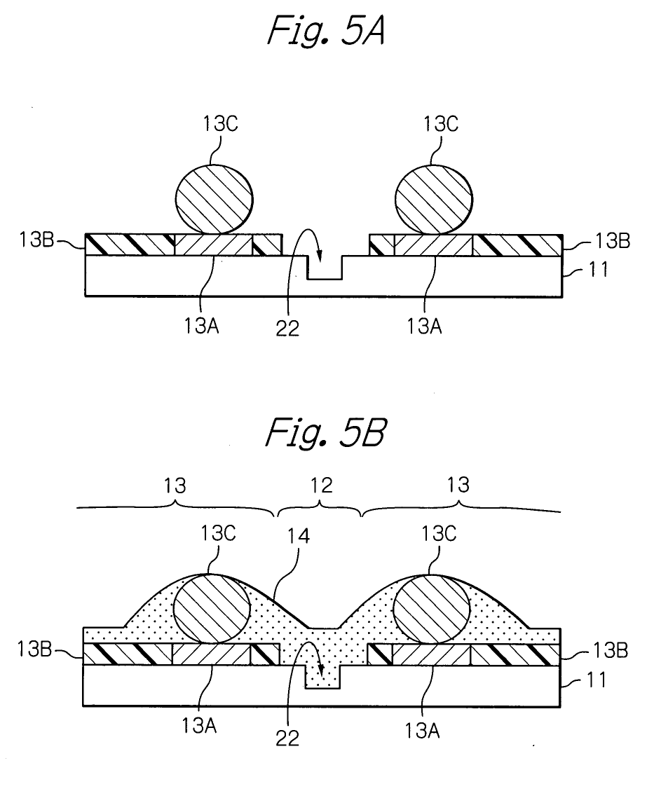

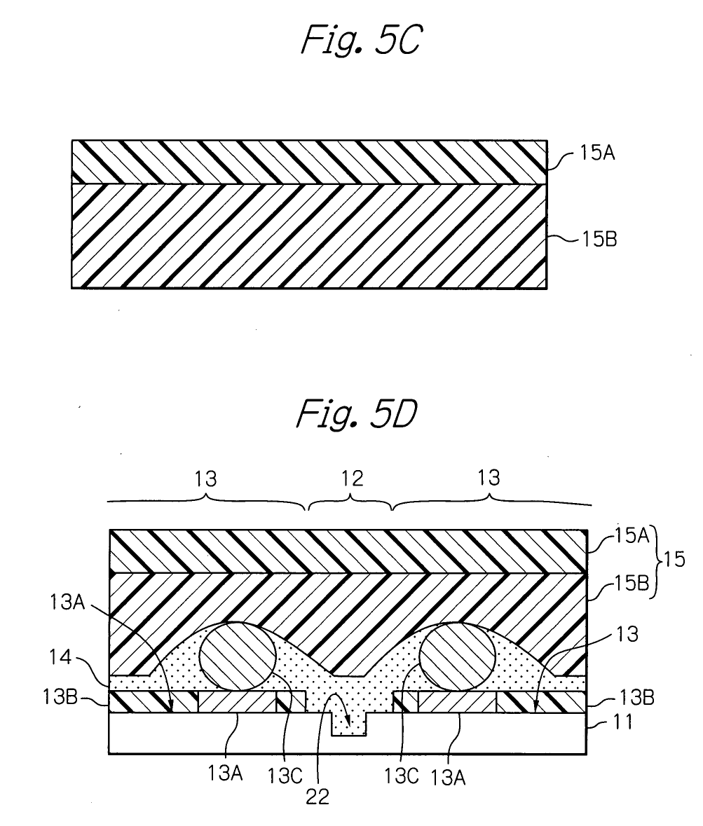

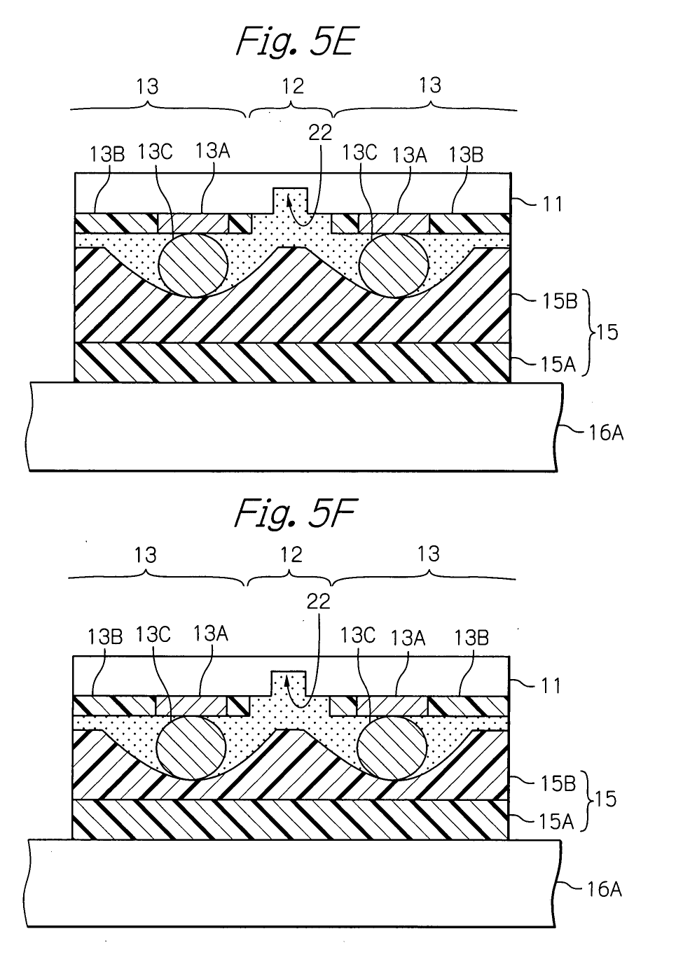

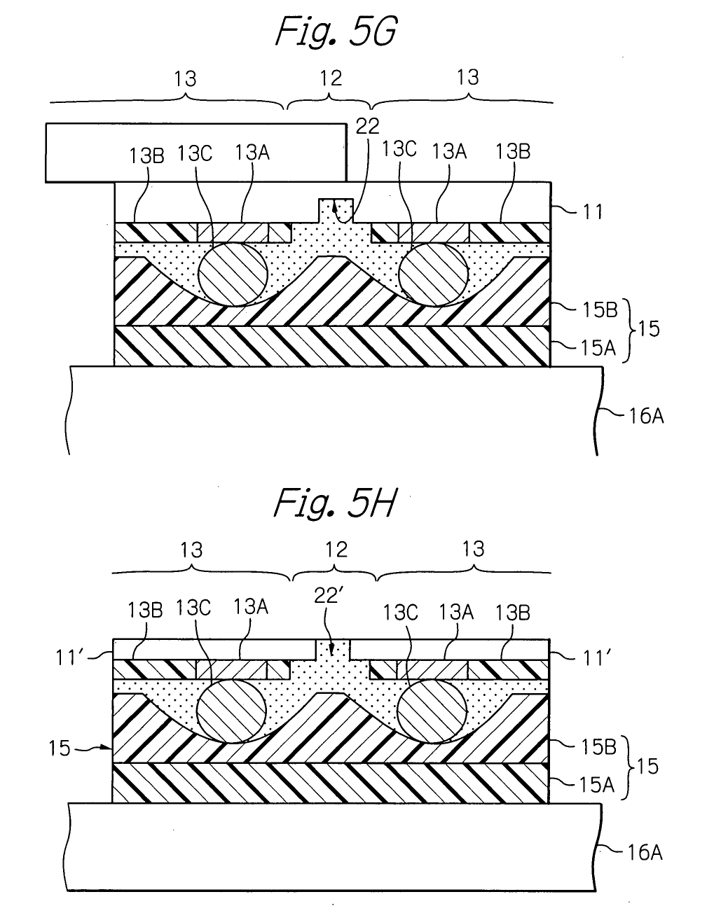

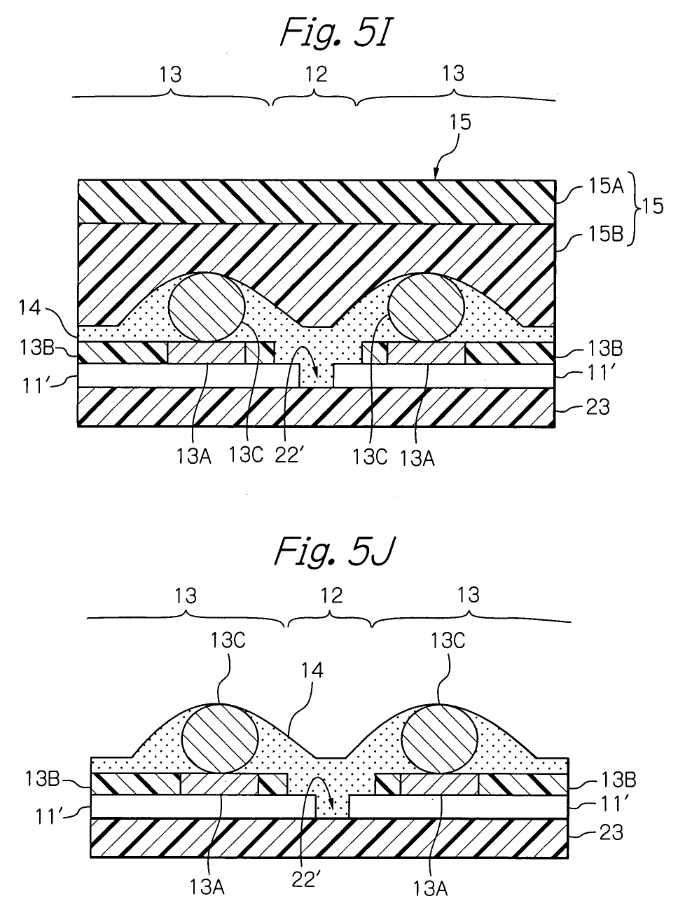

With reference to FIGS. 5A to 5J which are partial cross-sectional views, a second embodiment of the method for processing a semiconductor wafer according to the present invention will now be explained below.

First, referring to FIG. 5A, a semiconductor wafer 11 such as a silicon wafer is prepared. The silicon wafer 11 is substantially identical to that of FIG. 1A except that a half-cut groove 22 is previously formed along the scribe line area 12. Note that the half-cut groove 22 has a depth which is larger than a thickness of the silicon wafer 11 to be reduced to a target value.

Next, referring to FIG. 5B, the front surface of the silicon wafer 11 is coated with liquid-like material to thereby form a liquid-like layer 14 on the front surface of the silicon wafer 11. The liquid-like layer 14 is composed of a suitable liquid-like material exhibiting a wettability to the silicon wafer 11, the electrode pads 13A, the polyimide layers 13B and the spherical solder bumps 13C. For example, for the liquid-like material, a liquid-like flux solution, a glycol-based solution containing polyvinyl alcohol, ethylene alcohol or the like, or an organic resist solution or the like may be used. Note that the liquid-like flux solution serves as an anti-oxidizing agent for the solder bumps 13C.

Similar to the above-mentioned first embodiment of FIGS. 1A to 1L, although there are many fine spatial nests on the front surface of the silicon wafer 11, the fine spatial nests are filled with the liquid-like material due to the wettability to the silicon wafer 11, the electrode pads 13A, the polyimide layers 13B and the spherical solder bumps 13C, as shown in FIG. 5B.

Also, the liquid-like layer 14 has a suitable viscosity and a suitable surface tension so that the liquid-like flux is prevented from flowing out of the front surface of the silicon wafer 11. That is, a surface of the liquid-like layer 14 is undulated due to the existence of the spherical solder bumps 13C, and the undulated surface of the flux layer is maintained due to both the suitable viscosity and the surface tension of the liquid-like flux.

On the other hand, referring to FIG. 5C, a holder sheet 15 is prepared. The holder sheet 15 is substantially identical to that of FIG. 1C. Namely, the holder sheet 15 includes a support layer 15A, and an adhesive layer 15B formed on a surface of the support layer 15A. Similar to the above-mentioned first embodiment of FIGS. 1A to 1L, although the adhesive layer 15B may be formed as an adhesive resin layer composed of, for example, low molecular polyolefin, it may be formed as a suitable prepolymer layer exhibiting either a thermosetting property or a photosetting property.

Next, referring to FIG. 5D, the liquid-like layer 14 is covered with the holder sheet 15 in a similar manner to that explained with reference to FIG. 1D.

Next, referring to FIG. 5E, the holder sheet 15 carrying the silicon wafer 11 is set on a suction stage 16A forming a part of a grinding machine (not shown) in a similar manner to that explained with reference to FIG. 1E. The suction stage 16A has a plurality of holes (not shown) formed in the top surface thereof, and the holes are communicated with a vacuum pump (not shown) forming another part of the grinding machine.

Next, referring to FIG. 5F, the holder sheet 15 is sucked against the top surface of the suction stage 16A by operating the aforesaid vacuum pump, so that the holder sheet 15 carrying the silicon wafer 11 is securely fixed on the suction stage 16A, with the adhesive layer 15B being compressed due to the suction force exerted on the holder sheet 15 by the suction stage 16A.

Next, referring to FIG. 5G, a grinding wheel 16B forming yet another part of the aforesaid grinding machine (not shown) is applied to and is moved on the rear surface of the silicon wafer 11 while an abrasive slurry (not shown) is supplied to the rear surface of the silicon wafer 11, whereby the silicon wafer 11 is subjected to a mechanical grinding process.

Next, referring to FIG. 5H, the mechanical grinding process of the silicon wafer 11 is continued until the thickness of the silicon wafer 11 is reduced to the target value. At this time, the silicon wafer 11 is separated into respective silicon substrates 11′ forming the semiconductor chip areas 13, due to the formation of the half-cut groove 22 having the depth larger than the aforesaid target value. Namely, the half-cut groove 22 is defined as an elongated opening 22′ for separating the semiconductor chip areas 13 from each other. In short, when the aforesaid mechanical grinding process is finished, the dicing process for separating the semiconductor chip areas 13 from each other is simultaneously completed.

Thereafter, the operation of the aforesaid vacuum pump is stopped so that the holder sheet 15 carrying the semiconductor substrates 11′ is released from the suction force exerted thereon by the suction stage 16A.

Next, referring to FIG. 5I, the holder sheet 15 carrying the semiconductor substrates 11′ is removed from the suction stage 16A, and an adhesive support sheet 23 having an adhesive coating (not shown) is adhered to rear surfaces of the silicon substrates 11′ Note that the dicing sheet 17 of FIGS. 1K and 1L may be substituted for the adhesive support sheet 23. Also, note that the adhesive support sheet 23 should be nonreactive to the fluid-like layer 14.

Next, referring to FIG. 5J, the holder sheet 15 is peeled from the liquid-like layer 14. At this time, it is possible to easily carry out the peeling of the holder sheet 15 from the separated silicon substrates 11′ due to the fact that the separated silicon substrates 11′ are adhered to and supported by the adhesive support sheet 23. Similar to the first embodiment of FIGS. 1A to 1L, each of the separated substrates 11′ carrying the electrode pads 13A, the polyimide layer 13B and the spherical solder bumps 13C is called a flip-chip type semiconductor device.

The adhesive coating of the adhesive support sheet 23 may exhibit a setting property such as a thermosetting property, a photosetting property or the like. For example, when the adhesive coating layer of the adhesive support sheet 23 exhibits the thermosetting property, the adhesive support sheet 23 is thermally heated so as to be set, whereby each of the flip-chip type semiconductor devices can easily come off from the adhesive support sheet 23. Also, when the adhesive coating layer of the adhesive support sheet 23 exhibits the photosetting property, the adhesive support sheet 23 is irradiated with suitable light rays such as ultraviolet rays so as to be set, whereby each of the flip-chip type semiconductor devices can easily come off from the adhesive support sheet 23.

In the above-mentioned comparative method of FIGS. 2A to 2F, when a similar half-cut groove to the half cut-groove 22 of the FIG. 5A, is previously formed along the scribe line area 12 (see: FIG. 2A), the semiconductor devices 13 are polluted with the abrasive slurry used in the mechanical grinding process, as stated below.

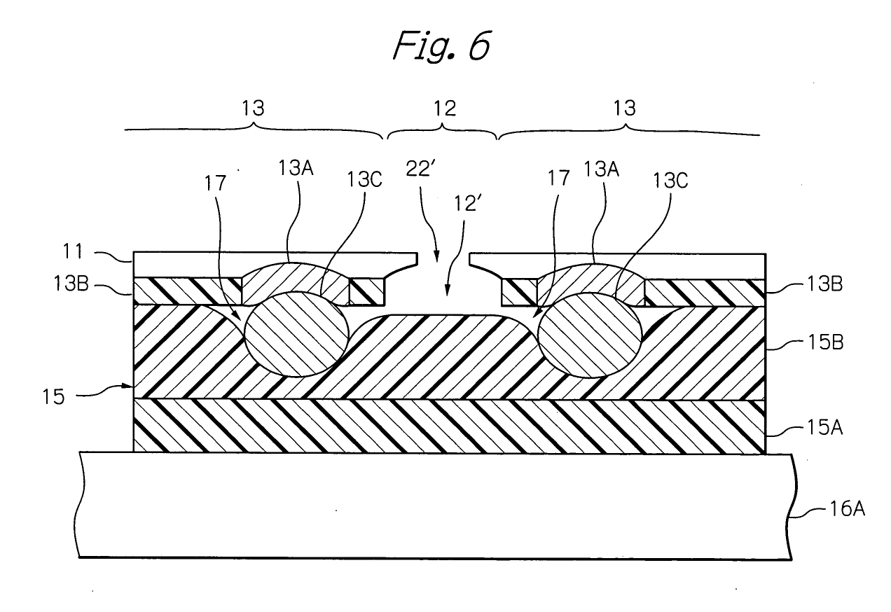

As shown in FIG. 6 corresponding to FIG. 2D, when the semiconductor chip areas 13 are separated from each other by an elongated opening 22′ which is derived from the aforesaid half-cut groove, the compressed air captured in the groove-like cavity 12′ is released and discharged into atmosphere through the elongated opening 22′, and the compressed air captured in the cavities 17 is also released and discharged into atmosphere through the groove-like cavity 12′ and the elongated opening 22′ so that the cavities 17 are communicated with the groove-like cavity 12′. Thus, during the mechanical grinding process, the abrasive slurry (not shown) penetrates into the cavities 17 through the elongated opening 22′ and the groove-like cavity 12′, resulting in the pollution of the semiconductor chip areas 13 with the abrasive slurry.

In the above-mentioned first and second embodiments, although each of the semiconductor chip areas 13 has the polyimide layer 13B formed on the front surface thereof, the polyimide layer 13B may be omitted, if necessary.

Finally, it will be understood by those skilled in the art that the foregoing description is of preferred embodiments of the method, and that various changes and modifications may be made to the present invention without departing from the spirit and scope thereof.

1. A method for processing a semiconductor wafer, having a plurality of solder bumps bonded on a front surface thereof, which method comprises:
forming a fluid-like layer on the front surface of said semiconductor wafer;
preparing a holder sheet having a support layer, and an adhesive layer formed on a surface of said support layer and exhibiting a fluidness;
covering said fluid-like layer with said holder sheet such that the adhesive layer of said holder sheet is rested on a surface of said fluid-like layer, with the adhesive layer of said holder sheet being transformable so as to conform with a configuration of the surface of said fluid-like layer due to the fluidness of the adhesive layer of said holder sheet;
mechanically grinding a rear surface of said semiconductor wafer so that a thickness of said semiconductor wafer is reduced to a target value; and
peeling said holder sheet from the surface of said fluid-like layer.

2. The method as set forth in claim 1, wherein said fluid-like layer is formed of an anti-oxidizing agent solution for preventing said solder bumps from being oxidized.

3. The method as set forth in claim 2, wherein said anti-oxidizing agent solution comprises a fluid-like flux solution.

4. The method as set forth in claim 1, further comprising removing said fluid-like layer from the front surface of said semiconductor wafer.

5. The method as set forth in claim 1, wherein said fluid-like layer exhibits a setting property.

6. The method as set forth in claim 5, further comprising partially setting said fluid-like layer after the formation of said fluid-like layer on the front surface of said semiconductor wafer is completed.

7. The method as set forth in claim 4, wherein said fluid-like layer is aqueous so that the removal of said fluid-like layer can be carried out with a water washing.

8. The method as set forth in claim 7, wherein said fluid-like layer is formed of a glycol-based solution.

9. The method as set forth in claim 7, wherein said fluid-like layer is formed of an organic resist solution.

10. The method as set forth in claim 1, wherein the adhesive layer of said holder sheet has a thickness larger than a height of the solder bumps.

11. The method as set forth in claim 1, wherein the adhesive layer of said holder sheet exhibits a high adhesive property to be allowed to be sufficiently adhered to the surface of said fluid-like layer.

12. The method as set forth in claim 11, further comprising lowering the adhesive property of the adhesive layer of said holder sheet before the peeling of said holder sheet from the surface of said fluid-like layer is carried out.

13. The method as set forth in claim 12, wherein the adhesive layer of said holder sheet exhibits a setting property, and said adhesive layer is set to thereby lower the adhesive property thereof.

14. The method as set forth in claim 13, wherein the setting property of said adhesive layer is a thermosetting property.

15. The method as set forth in claim 13, wherein the setting property of said adhesive layer is a photosetting property.

16. The method as set forth in claim 1, further comprising:
adhering a dicing sheet to the rear surface of said semiconductor wafer after the mechanical grinding of said rear surface is completed; and
dicing said semiconductor wafer so as to be cut into a plurality of semiconductor devices.

17. The method as set forth in claim 16 wherein said dicing sheet exhibits a setting property, with said dicing sheet being set so that said semiconductor devices can easily come off said dicing sheet.

18. The method as set forth in claim 1, further comprising:
forming half-cut grooves in the front surface of said semiconductor wafer along scribe lines defined thereon, before the formation of said fluid-like layer on the front surface of said semiconductor wafer is carried out, each of said half-cut grooves having a depth which is larger than said target value so that said semiconductor wafer is separated into a plurality of semiconductor devices when the mechanical grinding of the rear surface of said semiconductor wafer is completed; and
adhering an adhesive support sheet to the rear surface of said semiconductor wafer.

19. The method as set forth in claim 18, wherein said adhesive support sheet exhibits a setting property, with said adhesive support sheet being set so that said semiconductor devices can easily come off said adhesive support sheet.

20. The method as set forth in claim 18, wherein said adhesive support sheet is nonreactive to said fluid-like layer.
